(19) United States
(12) Patent Application Publication
(10) Pub. No.: US 2009/0222712 A1
(43) Pub. Date: Sep. 3, 2009

(54) DECODING SCHEME FOR CORRECTING BOTH ERASURES AND ERRORS OF REED-SOLOMON CODES IN A DIGITAL COMMUNICATION SYSTEM

(75) Inventors: YAN ZHONG, SAN JOSE, CA (US); LEI CHEN, SANTA CLARA, CA (US)

Correspondence Address: FRANK F. TIAN, 331-4A THIRD AVENUE, LONG BEACH, NJ, 07740, US

(73) Assignee: LEGEND SILICON CORP., FREMONT, CA (US)

(21) Appl. No.: 12/041,514

(22) Filed: Mar. 3, 2008

(51) Int. Cl. H03M 13/37; G06F 11/10

(52) U.S. Cl. 714/793; 714/E11.032

(57) ABSTRACT

A method for correcting both erasures and errors of Reed-Solomon codes in a digital communication system is provided. The method comprises the steps of: calculating a syndrome; calculating a set of erasure locations; replacing errata evaluator polynomial by a function having a difference value; and replacing errata locator polynomial by a function having the difference value.

### FIELD OF THE INVENTION

The present invention relates generally to decoding systems. More specifically, the present invention relates to an improved decoding scheme and implementation for correcting both erasures and errors of Reed-Solomon codes in a digital communication system.

### BACKGROUND

It is known that Reed-Solomon codes can be used for correcting both erasures and errors such that signal to noise ratio are reduced. An article by T_K Truong, et al entitled “A NEW DECODING ALGORITHM FOR CORRECTING BOTH ERASURES AND ERROR OF REED-SOLOMON CODES” which is hereby incorporated herein by reference (IEEE Transaction on Communications. VOL. 51, No. 3, March 2003) discloses a decoding algorithm that computes the errata locator polynomial and the errata evaluator polynomial simultaeously without performing polynomial divisions.

To fit a specific code length into a communication systems such as advanced television systems committee (ATSC) system, improved devices are required.

### SUMMARY OF THE INVENTION

An improved decoding scheme for correcting both erasures and errors of Reed-Solomon codes in a digital communication system having a Novel iterative method including the initial condition settings is provided.

An improved decoding scheme for correcting both erasures and errors of Reed-Solomon codes in a digital communication system having a scheme having shortened the code parameters 2^{m}−1 to fit ATSC standard is provided.

An improved decoding scheme for correcting both erasures and errors of Reed-Solomon codes in a digital communication system having a Reducing logic or circuit complexity by 4xCLK is provided.

A method for correcting both erasures and errors of Reed-Solomon codes in a digital communication system is provided. The method comprises the steps of: calculating a syndrome; calculating a set of erasure locations; replacing errata evaluator polynomial by a function having a difference value; and replacing errata locator polynomial by a function having the difference value.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is an example of a block diagram in accordance with some embodiments of the invention.

FIG. 2 is an example of a first flowchart in accordance with some embodiments of the invention.

FIG. 3A is a first example of reduced logic or circuit complexity in accordance with some embodiments of the invention.

FIG. 3B is a second example of reduced logic or circuit complexity in accordance with some embodiments of the invention.

FIG. 4 is an example of a second flowchart in accordance with some embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to a novel iterative method including the initial condition settings to accommodate a Shortening of the code parameters to fit ATSC standard, as well as having a Reduced logic or circuit complexity. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain non-processor circuits, some, most, or all of the functions of relating to novel iterative method including the initial condition settings to accommodate a Shortening of the code parameters to fit ATSC standard, as well as having a Reduced logic or circuit complexity. In the exemplified embodiments, it is noted that the processors include Finite State Machines, which are used in the preferred embodiment. The non-processor circuits may include, but are not limited to, a radio receiver, a radio transmitter, signal drivers, clock circuits, power source circuits, and user input devices. As such, these functions may be interpreted as steps of a method with novel iterative method including the initial condition settings to accommodate a Shortening of the code parameters to fit ATSC standard, as well as having a reduced logic or circuit complexity. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

For Reed-Solomon cyclic code, a generator polynomial g(X) with symbols from GF(2^{m}) has α, α², . . . , α^{2t}, αⁱ is all its roots. Because a is an element of GF(2^{m}), its minimal polynomial is simply φᵢ(X)=X−αⁱ, we have:

g(X)=g₀+g₁X+g₂X²+ . . . , +g₂ₜ₋₁X^{2t-1}+X^{2t} Eq. 1

g(X) generates a 2^{m} array cyclic code of length n=q−1 with exactly 2t parity check symbols. Further, the Reed-Solomon cyclic code satisfies the following conditions:

block length: n=2^{m}−1,

number of parity check symbols: n−k=2t,

dimension: k=2^{m}−1−2t,

minimum distance: dₘᵢₙ=2t+1.

In order to fit the Reed-Solomon cyclic code into our scheme, we have to shorten (255, 235) to (207, 187). we have:

255−48=207

235−48=187

n−k=20=2t, then,

t=10. Note that t denotes the maximum number of error that can be corrected in the system. As can be seen, the present scheme do not satisfy the 2^{m} requirement in GF(2^{m}), where m=8. Therefore, an adjustment is required. It is noted that (255, 235) can be generalized to other suitable numeral pairs in a Reed-Solomon cyclic code system.

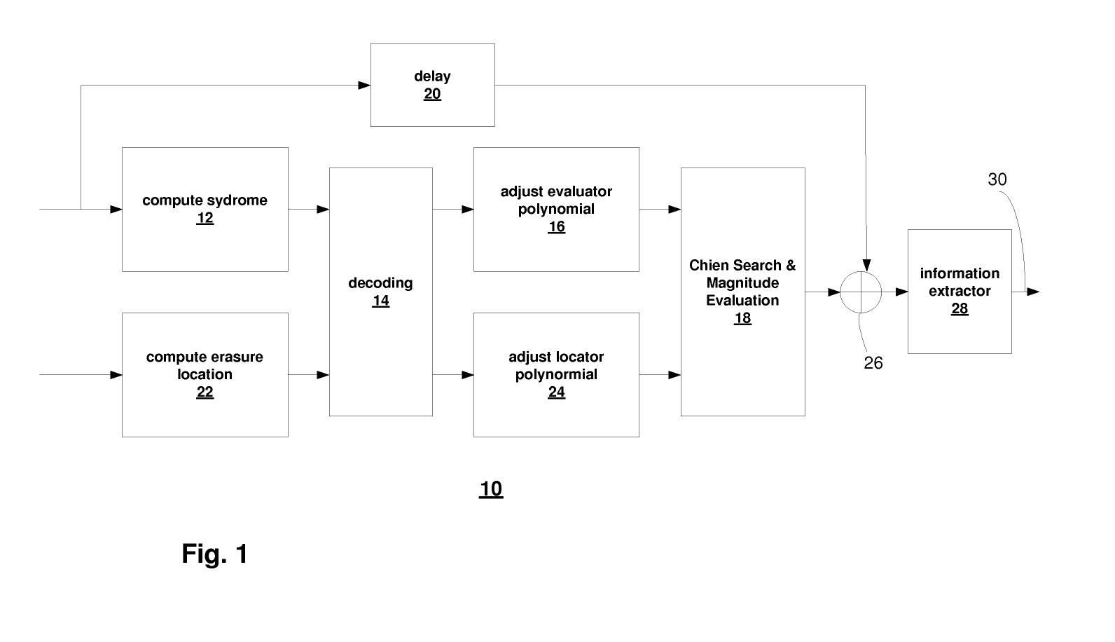

Referring to FIG. 1, a block diagram 10 in accordance with some embodiments of the invention is shown. First, in a first input wherein a received vector r₀ r₁ . . . rₙ₋₁ is input into a syndrome computation block 12 wherein a set of syndrome S₂ₜ₋₁, . . . , S₂, S₁ S₀ is computed. The computed syndrome is decoded 14. The decoded information is further adjusted, i.e. errata evaluator polynomial Ω^{(c)}(x) is adjusted by block 16. The adjustment process is further described in other figures of the present invention. The adjusted evaluator polynomial is subjected to Chien search and magnitude evaluation 18, wherein a set of errata vector, is output based on the errata evaluator polynomial and the errata locator polynomial described infra. A delayed information 20 of the received vector r₀ r₁ . . . rₙ₋₁ from the input end to syndrome computing block 12 is fed forward to and an adder 26. Second, in a second input at least one erasure location indicator is input into block 22, wherein at least one erasure location is computed 22. Similarly, the computed erasure location(s) Z_{d-1}, . . . , Z₂, Z₁ is(are) decoded in block 14 as well. The decoded location information, i.e. the errata locator polynomial Λ^{(c)}(x) is further adjusted in the form of adjusted locator polynomial in block 24. Similarly, the adjustment process is further described in other figures of the present invention. The adjusted locator polynomial is subjected to Chien search and magnitude evaluation by block 18 as well. The searched and evaluated information from both the first and second inputs are input into the adder 26 along with delayed information 20 with a corrected vector emerges as the output. The sum of the added information, in turn, is subjected to information extractor 28. The extracted information 30 is used downstream as the retrieved information.

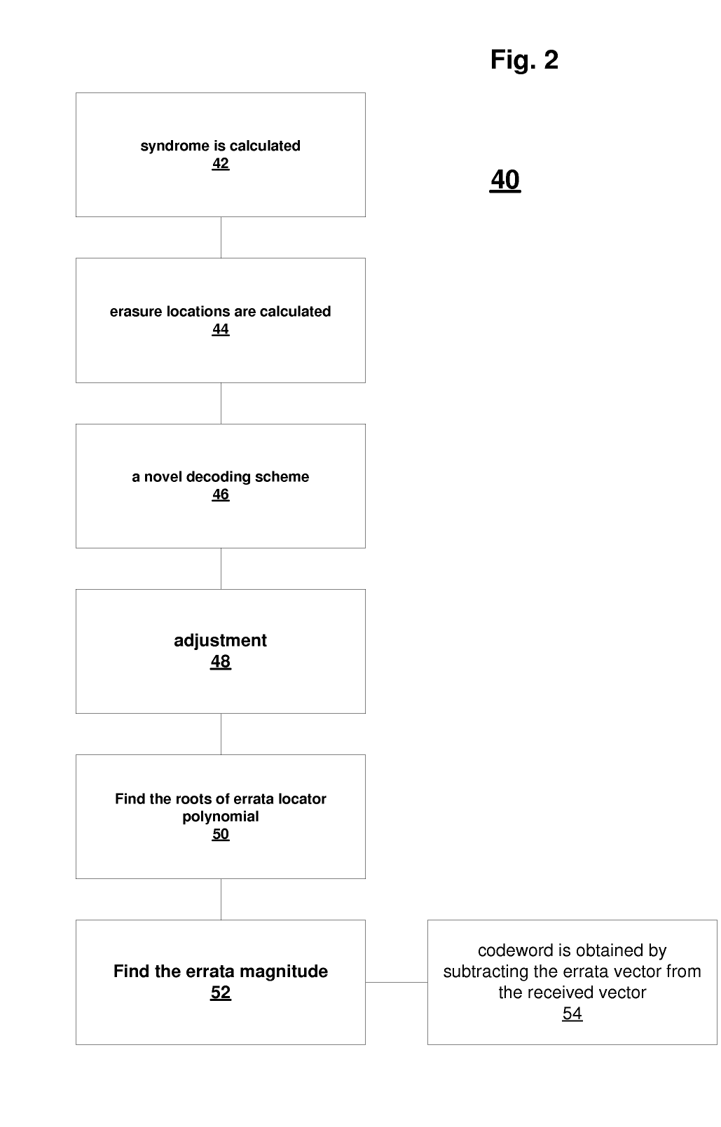

Referring to FIG. 2, a novel decoding scheme 40 for correcting both erasures and error of Reed-Solomon codes is derived or provided herein. First, decoding step is described (Step 42). The syndrome is calculated.

$${S}_{0} = r ( {α}^{0} ) = {r}_{0} + {r}_{1} + {r}_{2} + … + {r}_{n - 1} \\ {S}_{1} = r ( α ) = {r}_{0} + {r}_{1} α + {r}_{2} {α}^{2} + … + {r}_{n - 1} {α}^{n - 1} \\ {S}_{2} = r ( {α}^{2} ) = {r}_{0} + {r}_{1} {α}^{2} + {r}_{2} {α}^{4} + … + {r}_{n - 1} ( {α}^{2 n - 1} ) \\ ⋮ \\ {S}_{2 t - 1} = r ( {α}^{2 t - 1} ) = {r}_{0} + {r}_{1} {α}^{( 2 t - 1 )} + {r}_{2} {α}^{2 ( 2 t - 1 )} + … + {r}_{n - 1} {α}^{( 2 t - 1 ) ( n - 1 )} \qquad Eq . 2$$

Then the syndrome polynomial is:

S(x)=S₀+S₁X+S₂X²+ . . . +S₂ₜ₋₁X^{2t-1} Eq. 3
Second step wherein erasure locations are calculated (Step 44). Error locations Z₀, Z₁, . . . Z₂ₜ are calculated as follows:

Z₀=1,

Zⱼ is the jth erasure location for 1≦j≦s (where s is the erasure number) and Zⱼ=0 for s+1≦j≦2t.

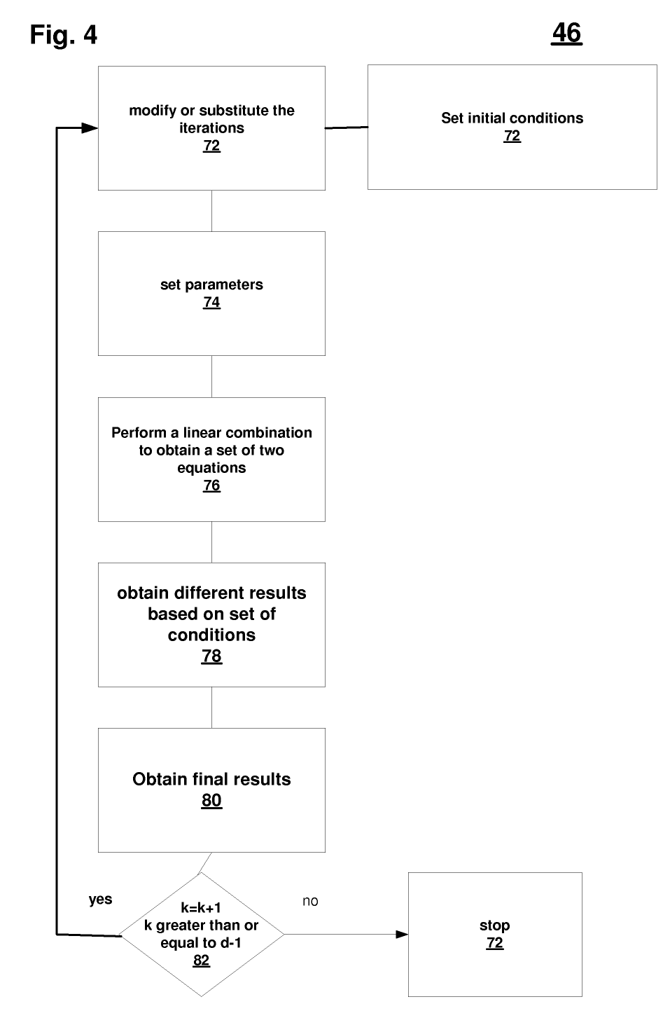

Third, a novel decoding scheme is provided herein including setting the following initial conditions (Step 46). For detailed description of the novel decoding scheme, refer to FIG. 4.
(1) Set initial conditions as follows. Initially set K=0, 1=0, and decode flag=0 and also set

Ω^{(a)}(x)=0, Λ^{(a)}(x)=0, Ω^{(b))}(x)=S(x), Λ^{(b))}(x)=1 (Step 70).
(2) Further, if k is non-zero, modify or substitute the iterations as follows:

Ω^{(b)}(x)←xΩ^{(b))}(x), and

Λ^{(b))}(x)←xΛ^{(b))}(x) (Step 72).
(3) If k>s then decode_flag=1 and the field elements δ, γ having their respective values as follows:

δ=Ω_{d}^{(b)} γ=Ω_{d}^{(a)}

else, δ=1, γ=Zₛ₊₁₋ₖ(Step 74).
(4) Perform a linear combination to obtain a set of two equations

Ω^{(c)}(x)=δΩ^{(a)}(x)+γΩ^{(b)}(x)

Λ^{(c)}(x)=δΛ^{(a)}(x)+γΛ^{(b)}(x) (Step 76).
(5) If decode_flag=1 and δ is non-zero and 21≦k−s−1,

Then Ω^{(a)}(x)=Ω^{(b)}(x); Λ^{(a)}(x)=Λ^{(b)}(x); and 1=k−s−1;

Else if k=s, then Ω^{(a)}(x)=X^{d};

Else if s is non-zero and k<s, then

Ω^{(a)}(x)=Ω^{(c)}(x) note that only zero bits are copied to n−k; and

Λ^{(a)}(x)=Λ^{(c)}(x) only zero bits are copied to n−k−1 (Step 78).
(6) Obtain final results as follows Ω^{(a)}(x)=Ω^{(c)}(x); Λ^{(a)}(x)=Λ^{(c)}(x) (Step 80).
(7) Set k=k+1, if k≦d−1, then goto step 72(Step 82).
(8) Otherwise, stop (Step 84).
(9) Thereby, we got an errata evaluator polynomial Ω^{(c)}(x); and an errato locator polynomial Λ^{(c)}(x) (Step 86).

4. Replace Ω₁ by Ω₁α⁴⁸ . . . , Ω₂ₜ₋₁ by Ω₂ₜ₋₁α^{48(2t-1)} in the errata evaluator polynomial; and similarly replace a difference value. Λ₁ by Λ₁α⁴⁸, Λ₂ by Λ₂α^{48x2} . . . , Λ₂ₜ by Λ₂ₜα^{48(2t)} in the errata locator polynomial (Step 48). Forty-eight happens to be the difference value in the instant case. Other difference values different than the number 48 are also contemplated in the present invention.

We denote the above as Ω1←Ω₁α⁴⁸, Ω₂←Ω₂α^{48x2} . . . , Ω₂ₜ₋₁←Ω₂ₜ₋₁α^{48(2t-1)} and

Λ₁←Λ₁α⁴⁸, Λ₂ Λ₂α^{48x2} . . . , Λ₂ₜ←Λ₂ₜ^{48(2t)}. This adjustment is required because the present scheme do not satisfy the 2^{m} requirement in GF(2^{m}).

5. Find the roots of errata locator polynomial Λ^{(c)}(x) by Chien's search method(Step 50). Then the errata locations are the inverse of the roots.

6. Find or calculate the errata magnitude by

$${\hat{W}}_{l} = \frac{Ω ( {\hat{Z}}_{l}^{- 1} )}{{Λ}^{′} ( {\hat{Z}}_{l}^{- 1} )}$$

For 1≦l≦s+1. Where each \hat{Z}ₗ is the erasure location among a plurality of locations, Ŵₗ is the erasure amplitude, and Λ′\hat{Z}ₗ⁻¹ is the derivative of Λ (Step 52).

7. The corrected codeword is obtained by subtracting the errata vector from the received vector (Step 54).

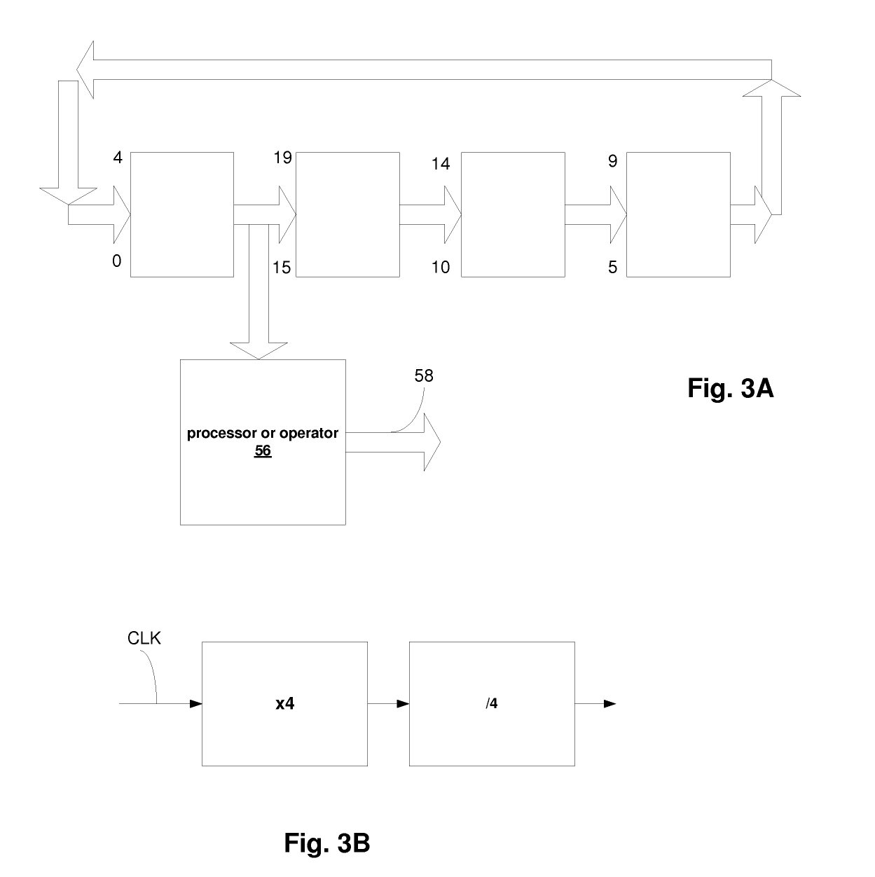

Referring to FIG. 3A, a first example of reduced logic or circuit complexity is shown. As can be seen, a 20 bit length system is change into a series of 4 steps. For example, if we have a twenty (20) bit word, from bit 0 to bit 19, instead of using twenty logic or circuit units, five, i.e. twenty divided by four (20/4=5) is used, each step only uses 5 bits. In other words, a 20 bit logic is reduced to a series wherein only 5 bits are processed at any given time. For example, after bits 0-4 are processed, the result may be fed to an operator or processor 56. The operator 56 may be an adder or a multiplexer, etc. In turn, bits 5-9 are processed; the result may be fed to the operator 56. Similarly, bits 10-14 and bits 15-19 are subsequently fed to the operator 56. The combined results 58 are output of processor 56. As can be seen, circuit logic is reduced to one quarter of the original while more time (a factor of 4) is needed. In order to maintain the same time frame, clock speed is increased by a factor of four for the processing of the 20 bits as shown in FIG. 3B.

Referring to FIG. 3B, a second example of reduced logic or circuit complexity is shown. In order to keep up with the system clock speed and reduce logic or circuit complexity, the system clock CLK is first increased by a factor of four (4) for FIG. 3A processing (x4). When FIG. 3A processing is performed, system clock CLK is restored back to its original speed (/4).

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. A method for correcting both erasures and errors of Reed-Solomon codes in a digital communication system comprising the steps of:
calculating a syndrome;
calculating a set of erasure locations;
replacing errata evaluator polynomial by a function having a difference value; and
replacing errata locator polynomial by a function having the difference value.

2. The method of claim 1 further comprising the step of providing a decoding scheme.

3. The method of claim 1 further comprising the step of finding roots of errata locator polynomial Λ^{(c)}(x) by Chien's search method.

4. The method of claim 1 further comprising the step of calculating at least one errata magnitude.

5. The method of claim 1 further comprising the step of subtracting an errata vector from a received vector.

6. The method of claim 1 further comprising the step of reducing logic or circuit complexity by multiplying system clock by a factor of n.

7. The method of claim 6 further comprising the step of restoring the system clock speed.

8. The method of claim 6, wherein the factor of n is equal to four.
